(19) United States
(12) Patent Application Publication
(10) Pub. No.: US 2022/0416505 A1
(43) Pub. Date: Dec. 29, 2022

(54) Directly Modulated Laser

(71) Applicant: Nippon Telegraph and Telephone Corporation, Tokyo (JP)

(72) Inventors: Suguru Yamaoka, Tokyo (JP); Ryo Nakao, Tokyo (JP); Shinji Matsuo, Tokyo (JP)

(21) Appl. No.: 17/777,818

(22) PCT Filed: Mar. 30, 2020
(86) PCT No.: PCT/JP2020/014478

§ 371 Date: May 18, 2022

(30) Foreign Application Priority Data
Dec. 9, 2019 (JP) PCTJP2019048115

(51) Int. Cl. H01S 5/125; H01S 5/026; H01S 5/0687

(52) U.S. Cl. CPC H01S 5/125; H01S 5/0265; H01S 5/0687

(57) ABSTRACT

A direct modulation laser includes a distributed feedback type laser active region and an optical feedback region optically connected to one end of the laser active region in a waveguide direction. The direct modulation laser performs laser oscillation by using photon-photon resonance (PPR) that occurs depending on a frequency difference between a frequency of light generated (oscillated) in the laser active region and a frequency of an FP mode in the optical feedback region.

### CROSS-REFERENCE TO RELATED APPLICATIONS

This application is a national phase entry of PCT Application No. PCT/JP2020/014478, filed on Mar. 30, 2020, which claims priority to Japanese Patent Application No. PCT/JP2019/048115, filed on Dec. 9, 2019, which applications are hereby incorporated herein by reference.

### TECHNICAL FIELD

The embodiments of the present invention relate to a direct modulation laser.

### BACKGROUND

Semiconductor devices are in widespread use as compact and low power consumption devices. A semiconductor laser, in particular, is a key component constituting an information communication system. Examples of such a semiconductor laser used in an information communication system firstly include an external modulation laser that is formed of a semiconductor laser provided externally with a modulator or the like and transmits a digital signal. The examples of a semiconductor laser used in an information communication system also include a direct modulation laser that modulates a current to be injected into an active region so as to directly superimpose a digital signal on output light.

The direct modulation laser is characterized by being lower in power consumption and in manufacturing cost than the external modulation laser and thus is widely used for short-distance communication or in places, such as a data center, where an extremely large number of information communication systems are required. The direct modulation laser, however, has been disadvantageous in that its modulation speed is slower than that of the external modulation laser for the following reason. That is, when an attempt is made to increase current injection for a high-speed operation, concurrently therewith, heat generation is markedly increased to decrease luminous efficiency of a semiconductor device, resulting in a failure to increase a modulation bandwidth.

In recent years, in order to solve such an intrinsic problem of a restricted bandwidth, there has been proposed a laser structure using a resonance phenomenon between photons (photon-photon resonance(PPR)). In the direct modulation laser using the PPR, a new resonance peak is made to appear in a high frequency region in which, conventionally, responsiveness is degraded (an output does not follow an input), and thus a significantly expanded modulation bandwidth is obtained (see, for example, Non-Patent Literature 1).

The direct modulation laser using a PPR effect has a structure in which, as shown in FIG. 17, a distributed feedback type (DFB) laser active region 401 and a passive waveguide 402 acting as an optical feedback mechanism are adjacently connected to each other. The laser active region 401 is optically connected to one end of the passive waveguide 402. Furthermore, both ends of the passive waveguide 402 function as a reflection point 403 and a reflection point 404. Laser light generated in the laser active region 401 interacts with a Fabry-Perot type resonance mode formed in an optical feedback region constituted by the passive waveguide 402, and PPR occurs when a phase matching condition is satisfied. In accordance with, for example, a change in refractive index caused by an injected current, the passive waveguide 402 switches between a state where PPR occurs and a state where no PPR occurs.

In the above-described prior art, a frequency at which responsiveness is enhanced by PPR is determined based on a free spectral range (FSR) defined by the length of the optical feedback region constituted by the passive waveguide 402 (see FIG. 18). FIG. 18 shows a transmission spectrum 411 in the laser active region 401 and a transmission spectrum 412 in the passive waveguide 402.

### Citation List

Non-Patent Literature

Non-Patent Literature 1: M. Radziunas et al., “Improving the Modulation Bandwidth in Semiconductor Lasers by Passive Feedback”, IEEE Journal of Selected Topics in Quantum Electronics, vol. 13, no. 1, pp. 136-142, 2007.

### SUMMARY

### Technical Problems

In the conventionally used technique, however, a frequency at which responsiveness is enhanced by PPR is determined based on the FSR of the optical feedback region, so that the length of the optical feedback region is determined by a frequency at which responsiveness is enhanced to a desired level. For example, in Non-Patent Literature 1, the length of the optical feedback region is set to 300 μm so that PPR occurs at about 43 GHz, with no room left for further size reduction. Because of this, operating the direct modulation laser using PPR requires to tune a refractive index or the like over the entire extent of the optical feedback region having such an increased length, which has led to problems such as difficulty in stabilizing the operation and an influence of an increase in power consumption or the like.

As described above, while the use of the PPR effect for a high-speed operation of the direct modulation laser is an indispensable technique for widening the bandwidth of the direct modulation laser, conventionally, obtaining the PPR effect at a desired frequency requires an increased device length and large-scale control of a refractive index, which has been disadvantageous.

The embodiments of the present invention have been made to solve the above-described problems, and an object of the embodiments of the present invention is to enable changing a frequency at which responsiveness is enhanced by PPR without the need to increase the length of the optical feedback region.

### Means for Solving the Problems

A direct modulation laser according to embodiments of the present invention includes a distributed feedback type laser active region formed on a substrate and a Fabry-Perot type optical feedback region having an optical waveguide structure, the optical feedback region being formed on the substrate, being optically connected to one end of the laser active region in a waveguide direction, and having reflection points formed at both ends thereof in the waveguide direction. The direct modulation laser performs laser oscillation by using photon-photon resonance that occurs depending on a frequency difference between a frequency of light generated in the laser active region and a frequency of a Fabry-Perot mode in the optical feedback region.

### Effects of Embodiments of the Invention

As discussed above, according to embodiments of the present invention, laser oscillation is performed using photon-photon resonance that occurs depending on a frequency difference between a frequency of light generated in the laser active region and a frequency of the Fabry-Perot mode in the optical feedback region, and thus it is possible to change a frequency at which responsiveness is enhanced by the PPR without the need to increase the length of the optical feedback region.

### BRIEF DESCRIPTION OF THE DRAWINGS

FIG. 1 is a configuration diagram showing a configuration of a direct modulation laser according to an embodiment of the present invention.

FIG. 2 is an explanatory view explaining how PPR occurs.

FIG. 3A is a sectional view showing the configuration of the direct modulation laser according to the embodiment of the present invention.

FIG. 3B is a sectional view showing a partial configuration of the direct modulation laser according to the embodiment of the present invention.

FIG. 4 is an explanatory view explaining how PPR occurs.

FIG. 5 is a sectional view showing a configuration of the direct modulation laser according to the embodiment of the present invention.

FIG. 6A is a sectional view showing a configuration of the direct modulation laser according to the embodiment of the present invention.

FIG. 6B is a sectional view showing a partial configuration of the direct modulation laser according to the embodiment of the present invention.

FIG. 7A is an explanatory view explaining how PPR occurs.

FIG. 7B is an explanatory view explaining how PPR occurs.

FIG. 8A is a sectional view showing a configuration of a direct modulation laser according to the embodiment of the present invention.

FIG. 8B is a perspective view showing the configuration of the direct modulation laser according to the embodiment of the present invention.

FIG. 9A is an explanatory view explaining how PPR occurs.

FIG. 9B is an explanatory view explaining how PPR occurs.

FIG. 9C is an explanatory view for explaining a −1st order mode and a ±2nd order mode generated by resonance between a high-order side mode (+1st order) that has arisen using FWM and a 0th order.

FIG. 9D is a characteristic diagram showing a relationship between a reflectance at a reflection point 104 and the width of a core 115 at the reflection point 104.

FIG. 10 is a sectional view showing a configuration of a direct modulation laser according to the embodiment of the present invention.

FIG. 11 is a sectional view showing a partial configuration of the direct modulation laser according to the embodiment of the present invention.

FIG. 12 is a perspective view showing a partial configuration of the direct modulation laser according to the embodiment of the present invention.

FIG. 13 is a perspective view showing a partial configuration of the direct modulation laser according to the embodiment of the present invention.

FIG. 14 is a sectional view showing a partial configuration of the direct modulation laser according to the embodiment of the present invention.

FIG. 15 is a sectional view showing a partial configuration of the direct modulation laser according to the embodiment of the present invention.

FIG. 16 is a plan view showing a partial configuration of the direct modulation laser according to the embodiment of the present invention.

FIG. 17 is a plan view showing a partial configuration of a conventional direct modulation laser.

FIG. 18 is an explanatory view explaining how PPR occurs conventionally.

### DETAILED DESCRIPTION OF ILLUSTRATIVE EMBODIMENTS

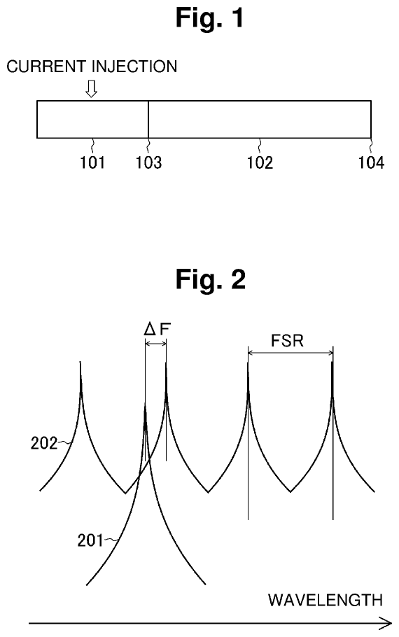

With reference to FIG. 1, the following describes a direct modulation laser according to an embodiment of the present invention. The direct modulation laser includes a distributed feedback type laser active region 101 and an optical feedback region 102 optically connected to one end of the laser active region 101 in a waveguide direction. At both ends of the optical feedback region 102 in the waveguide direction, there are formed, respectively, reflection points 103 and 104 at which reflection occurs. Furthermore, the optical feedback region 102 has an optical waveguide structure and a Fabry-Perot type resonator structure enabling a Fabry-Perot (FP) mode to be formed therein. In the optical feedback region 102, there can be also formed a combined mode of the optical feedback region 102 and the laser active region 101.

In addition, the direct modulation laser performs laser oscillation by using photon-photon resonance (PPR) that occurs depending on a frequency difference between a frequency of light generated (oscillated) in the laser active region 101 and a frequency of the FP mode in the optical feedback region 102. As shown in FIG. 2, the PPR occurs depending on a frequency difference ΔF between a peak wavelength of a transmission spectrum 201 in the laser active region 101 (a peak wavelength in an oscillation wavelength range) and a peak wavelength of a transmission spectrum 202 in the optical feedback region 102 (a peak wavelength of the FP mode).

Thus, the direct modulation laser according to the embodiment enables PPR to occur regardless of the length of the optical feedback region 102 in the waveguide direction. As a result, the direct modulation laser according to the embodiment makes it possible to obtain a wide modulation bandwidth by using PPR, with a device length reduced, the wide modulation bandwidth enabling high-speed direct modulation, and to stably exert an effect of the PPR, thus obtaining a high-speed direct modulation laser with high controllability.

The direct modulation laser includes, for example, a frequency adjustment mechanism and thus is capable of adjusting a frequency of the Fabry-Perot mode in the optical feedback region 102. The frequency adjustment mechanism adjusts a frequency of the Fabry-Perot mode by injecting a current into the optical feedback region 102, by controlling a temperature in the optical feedback region 102, or by applying an electric field to the optical feedback region 102. For example, frequency control can be achieved by providing, in the optical feedback region 102, a resistance heating type heater made of a metal such as tantalum as a temperature control mechanism.

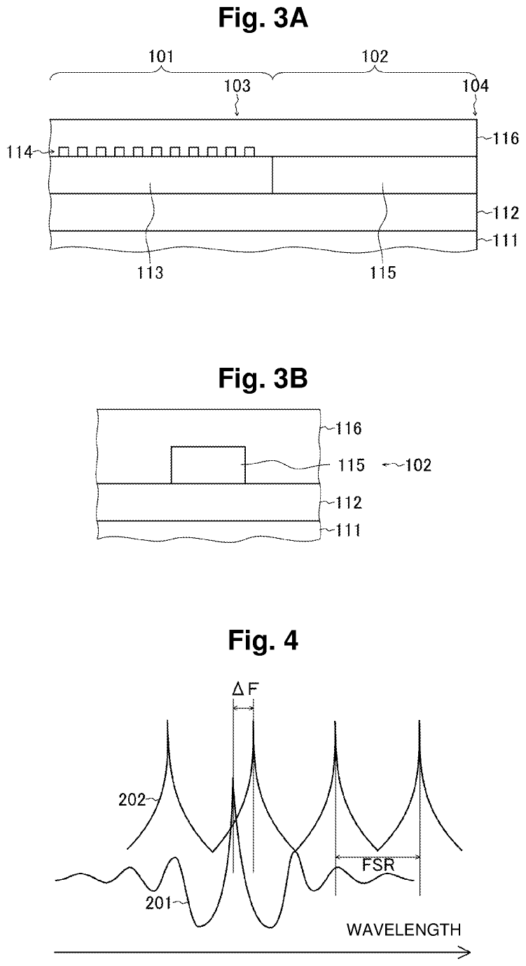

Next, with reference to FIGS. 3A and 3B, a further detailed description is given of the direct modulation laser according to the embodiment of the present invention. FIG. 3A shows a section along a plane parallel to the waveguide direction, and FIG. 3B shows a section along a plane perpendicular to the waveguide direction. The direct modulation laser includes a substrate in and a lower clad layer 112 formed on the substrate in. The substrate 111 is made of, for example, an n-type InP obtained by doping InP with Si. The lower clad layer 112 is made of, for example, an n-type InP.

In the laser active region 101, an active layer 113 is formed on the lower clad layer 112, and a diffraction grating 114 is formed on the active layer 113. The active layer 113 has, for example, a multiple quantum well structure made of InGaAsP or InGaAlAs. The diffraction grating 114 is composed of a concave portion and a convex portion adjacent to the concave portion, which are arranged in the waveguide direction. In the diffraction grating 114, in a part (central portion) thereof in the waveguide direction, there is formed a portion (¼ shift portion) whose phase is inverted by π. A phase shift of this portion, namely the ¼ shift portion, enables single mode light emission at a Bragg wavelength.

Furthermore, a core 115 is formed in the optical feedback region 102. The core 115 is made of, for example, InGaₓAl₁₋ₓAs whose lattice constant in a plane direction of the substrate 111 is lattice-matched with InP.

An upper clad layer 116 is formed on the active layer 113 and the core 115. For example, the active layer 113 extends in the waveguide direction and has a sectional shape perpendicular to the waveguide direction identical to that of the core 115. Furthermore, the upper clad layer 116 covers the active layer 113 and the core 115 and is formed above the lower clad layer 112. The upper clad layer 116 is made of, for example, InP. A part of the upper clad layer 116 lying on the active layer 113 is of, for example, a p-type. Furthermore, the other areas of the upper clad layer 116 including a part thereof lying on the core 115 are of an i-type (non-doped).

In the laser active region 101, the n-type lower clad layer 112, the active layer 113, which is of the i-type, and a p-type area of the upper clad layer 116 are stacked in a thickness direction (a direction of a normal to a plane of the substrate 111) to form a so-called vertical n-i-p structure. In this case, the lower clad layer 112 and the p-type area of the upper clad layer 116 form a current injection structure.

For example, the laser active region 101 having an optical waveguide structure including the active layer 113 as a core and the optical feedback region 102 having the optical waveguide structure including the core 115 can be formed by being directly joined to each other. With this configuration, light traveling from the optical feedback region 102 to the laser active region 101 is reflected off a reflection portion constituted by the diffraction grating 114 in the laser active region 101, and thus the reflection point 103 is effectively formed. A position of the reflection point 103 thus configured deviates from a boundary between the laser active region 101 and the optical feedback region 102 by a penetration depth of light.

The reflection point 104 can be formed by forming a cleavage plane at an end of the optical feedback region 102 opposite to a connection end thereof with the laser active region 101. It can be formed also by forming an end face of the optical feedback region 102 by dicing. By Fresnel reflection at an interface between a semiconductor and surrounding air on the end face thus formed, the reflection point 104 can be formed. The reflection points 103 and 104 can also be formed using other structures.

The above-described layer configurations formed of compound semiconductors can be formed by, for example, epitaxial growth using a known organic metal vapor deposition method or the like. Furthermore, the diffraction grating 114, the core, and so on can be formed by processing (patterning) using known lithography and etching techniques.

In the direct modulation laser, as shown in FIG. 4, the transmission spectrum 201 in the laser active region 101 has a peak at a certain wavelength. As described earlier, the direct modulation laser according to the embodiment depends not on an interval between FP mode peaks of the transmission spectrum 202 in the optical feedback region 102 but on the frequency difference ΔF between peaks of the modes. Thus, the direct modulation laser can be freely designed without being limited by a device length (the length of the optical feedback region 102 in the waveguide direction). This makes it possible to reduce the length of the optical feedback region 102 and consequently to obtain a wideband direct modulation laser, with a device length reduced.

By the way, increasing the bandwidth using PPR depends on the frequency difference ΔF. On the other hand, an oscillation wavelength in the laser active region 101 changes due to an ambient temperature and heat generation caused by current injection, thus shifting toward a long wavelength side. Furthermore, a peak wavelength (frequency) in the optical feedback region 102 is defined approximately by an ambient temperature. This means that, for the occurrence of PPR, wavelength adjustment in the laser active region 101 and wavelength adjustment in the optical feedback region 102 can be independently performed, indicating that PPR occurrence control is facilitated.

Furthermore, in order to allow PPR to stably occur in any of the above-described states, to change a frequency at which PPR occurs, or to buffer manufacturing variations in device length and in refractive index, an adjustment mechanism is provided in the optical feedback region 102 so as to enable a more stable operation. The adjustment mechanism can be formed of, for example, a heater. The fact that the optical feedback region 102 can be designed to have a reduced length means that power required for such an adjustment mechanism can also be reduced, and thus it is possible to improve stability and to reduce power consumption. The addition of the adjustment mechanism is not necessary, and the adjustment mechanism can also be formed of a configuration other than a heater.

Next, a description is given of other configurations of the reflection points 103 and 104. For example, the core 115 of the optical feedback region 102 is butt-coupled to the active layer 113 (core) of the laser active region 101, the core 115 being configured as a structure different in at least one of thickness and width from the active layer 113 of the laser active region 101, and a connection point therebetween can be used as the reflection point 103.

Furthermore, also when the active layer 113 and the core 115 are made respectively of materials having different refractive indices from each other, a connection point between the laser active region 101 and the optical feedback region 102 can be used as the reflection point 103. For example, when the active layer 113 has a multiple quantum structure using InGaAlAs and the core 115 is made of InGaAlAs or InGaAsP, the reflection point 103 can be formed.

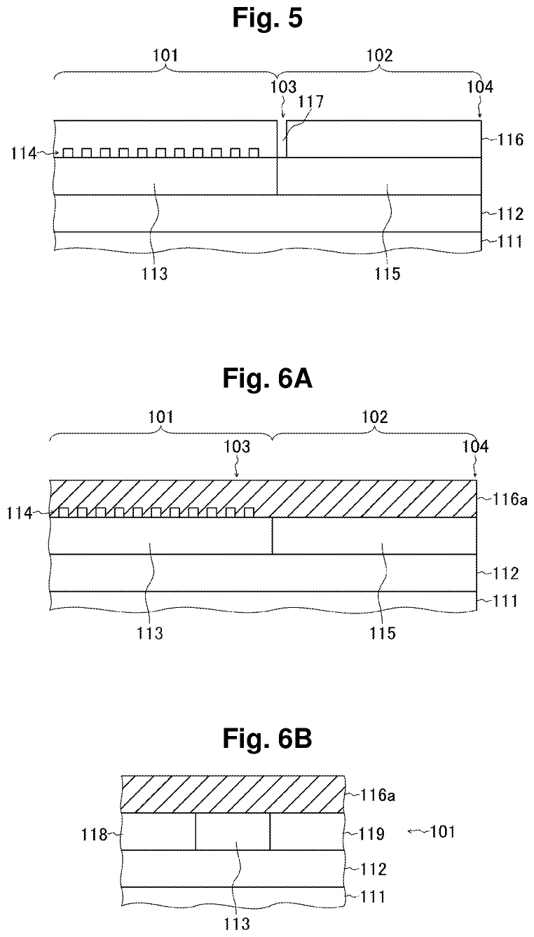

Furthermore, as shown in FIG. 5, at a connection point in the upper clad layer 116 between the laser active region 101 and the optical feedback region 102, a groove 117 is formed to extend in a direction intersecting the waveguide direction, and thus also in this case, the reflection point 103 can be formed. By forming the groove 117, an inflection point of a refractive index is formed at this point, and thus the groove 117 can be used as the reflection point 103. FIG. 5 shows a section along a plane parallel to the waveguide direction.

Next, with reference to FIGS. 6A and 6B, a description is given of another current injection structure in the laser active region 101. FIG. 6A shows a section along a plane parallel to the waveguide direction, and FIG. 6B shows a section along a plane perpendicular to the waveguide direction. In this current injection structure, the laser active region 101 includes a current injection mechanism that injects a current in the plane direction of the substrate 111, and in the laser active region 101, an n-type layer 118 and a p-type layer 119 are arranged with the active layer 113 interposed therebetween. The n-type layer 118 is made of, for example, n-type InP, and the p-type layer 119 is made of, for example, p-type InP. In this configuration, the substrate 111 and the lower clad layer 112 are made of SiC, and an upper clad layer 116a is made of silicon oxide. This structure is of a so-called lateral current injection type.

In order to achieve light confinement in the active layer 113, the lower clad layer 112 is made of a material having a refractive index lower than that of a material forming the active layer 113. For example, the lower clad layer 112 (substrate 111) can also be made of, without being limited to SiC, AlN, GaN, SiO₂, AlGaAs, or the like. When the lower clad layer 112 is made of SiO₂, the substrate 111 can be made of Si. When the lower clad layer 112 is made of AlGaAs, the substrate 111 can be made of GaAs.

In the above-described laser active region 101 of the lateral current injection type, a difference in refractive index between the lower clad layer 112, the upper clad layer 116a, and the active layer 113 (core 115) can be increased, and thus light can be more strongly confined in the active layer 113. This stronger light confinement can further enhance an interaction between light fed back from the optical feedback region 102 and light in the laser active region 101. As a result of these facts, it is possible to increase the bandwidth by using PPR without increasing a reflected returning component from the laser active region 101.

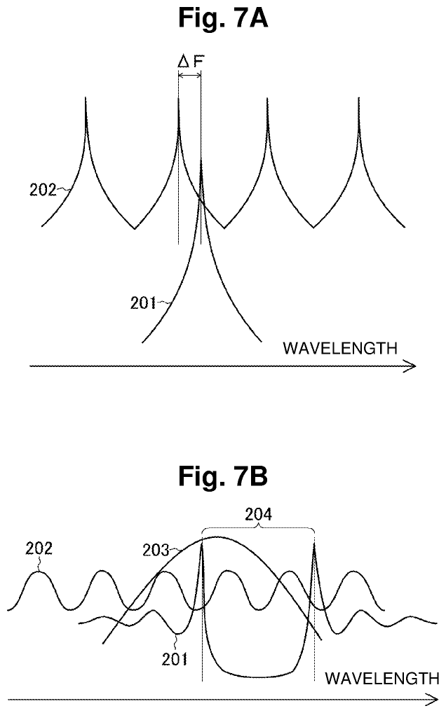

Furthermore, as described above, strong light confinement eliminates the need to increase a reflectance in the optical feedback region 102, thus eliminating the need to form a high reflectance (HR) coating or a distributed Bragg reflector (DBR) grating on an end face of the optical feedback region 102, so that structure formation is facilitated. Furthermore, when the interaction is enhanced as described above, as shown in FIG. 7A, PPR occurs even in a case where the frequency difference ΔF between the transmission spectrum 201 in the laser active region 101 and the transmission spectrum 202 in the optical feedback region 102 is large, so that designing is enabled such that the bandwidth is increased in a high frequency region.

Moreover, in a structure in which light confinement in a substrate perpendicular (thickness) direction is achieved using a difference between refractive indices of group III-V semiconductors/insulators (air, SiO₂, and so on) and low-refractive-index semiconductors (SiC, AlN, and so on), the diffraction grating 114 with a high degree of refractive index modulation can be formed in the laser active region 101, and thus it is possible to obtain the laser active region 101 constituted by the diffraction grating 114 having a large coupling coefficient.

When the diffraction grating 114 has a large coupling coefficient, as shown in FIG. 7B, the width of a stopband 204 in the laser active region 101 is increased, so that most of maximum peaks of the transmission spectrum 202 in the optical feedback region 102 fall within the stopband 204. As a result, it is unlikely that a laser operation becomes unstable due to interference between a peak of oscillation light in the laser active region 101 and a peak of the FP mode in the optical feedback region 102.

In a DFB laser using a general diffraction grating having a small coupling coefficient, the FP mode hardly falls within a stopband of the DFB laser, so that it is likely that an operation becomes unstable due to interference between the FP mode and a DFB mode.

Furthermore, while adjusting a gain spectrum 203 of an active layer material can also affect an operation, the above-described case allows only a reduced number of DFB and FP mode peaks to be selected compared with a case of having a smaller coupling coefficient, thus enabling a single mode operation and a stable (ease of occurrence of mode-hopping or PPR) operation.

By the way, in a case where there is a large difference in refraction index between the active layer 113 and a layer on top of or underneath the active layer 113 and the diffraction grating 114 has a large coupling coefficient, a reflectance at the reflection point 103 formed by reflection off the reflection portion constituted by the diffraction grating 114 is increased. Thus, this configuration can increase the strength of optical feedback by the optical feedback region 102. As a result, PPR occurs even in a state where there is a large frequency difference between a transmission spectrum in the laser active region 101 and a transmission spectrum in the optical feedback region 102 (a frequency at which responsiveness is enhanced is high), and thus the bandwidth can be increased.

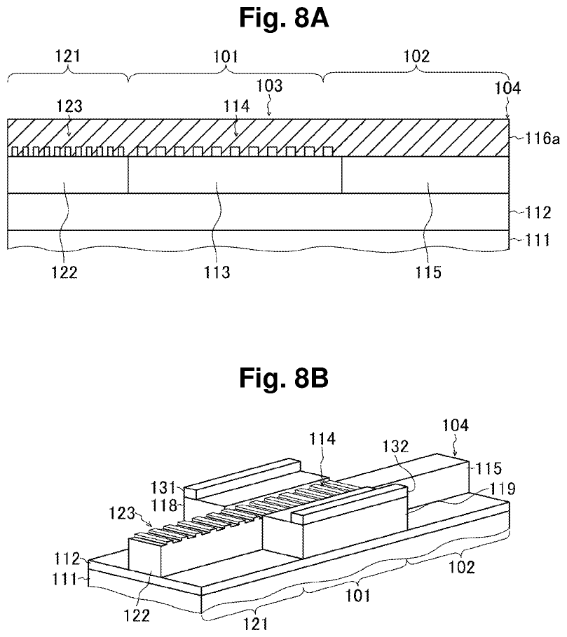

Next, with reference to FIGS. 8A and 8B, a description is given of another direct modulation laser according to the embodiment of the present invention. FIG. 8A shows a section along a plane parallel to the waveguide direction. The direct modulation laser further includes a DBR region 121 formed on the substrate 111 and optically connected to the other end of the laser active region 101 in the waveguide direction. In the DBR region 121, a core 123 is formed above the lower clad layer 112. The core 123 can be made of, for example, InGaAlAs. Furthermore, in the laser active region 101, as a current injection mechanism, the n-type layer 118 and the p-type layer 119 are arranged with the active layer 113 interposed therebetween. Furthermore, an n electrode 131 is formed on the n-type layer 118, and a p electrode 132 is formed on the p-type layer 119. In FIG. 8B, depiction of the upper clad layer 116a is omitted. Other configurations are similar to those of the direct modulation laser using the lateral current injection type laser active region 101 described with reference to FIGS. 6A and 6B, and detailed description thereof will be omitted.

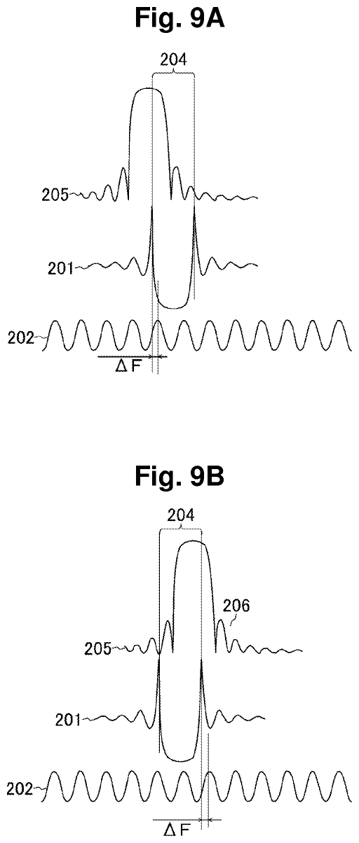

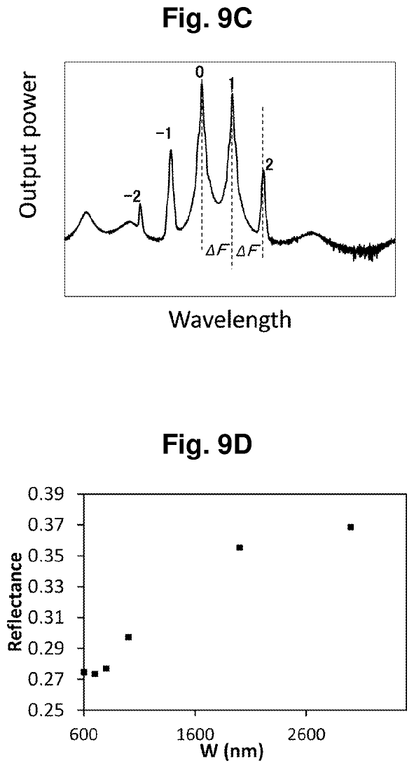

In the direct modulation laser, in the DBR region 121, for example, a transmission peak on a short wave side of the laser active region 101 can be selected and used to perform a laser operation and to increase the bandwidth by using PPR. In this case, as shown in FIG. 9A, in the stopband 204 of the transmission spectrum 201 in the laser active region 101, fringe peaks and FP mode peaks on a longer wavelength side than a peak wavelength of a reflection spectrum 205 in the DBR region 121 are concentrated. As a result, most of modes in a region on a slightly longer wavelength side than a peak of the transmission spectrum 201, which is important for the occurrence of PPR, are attenuated, and thus a stable single-mode operation and the occurrence of PPR are enabled.

On the other hand, when, in the DBR region 121, a transmission peak on a long wavelength side of the laser active region 101 is selected, as shown in FIG. 9B, in a region on a longer wavelength side than a peak (the stopband 204) of the transmission spectrum 201, there are a plurality of fringe peaks 206 in the DBR region 121 and FP mode peaks of the transmission spectrum 202, so that a laser operation and the occurrence of PPR become unstable. For this reason, in the direct modulation laser including the DBR region 121, in order to expand a bandwidth by using PPR, it is important from a design viewpoint to select, as a target of reflection in the DBR region 121, a short-wave-side peak of oscillation light in the laser active region 101.

Furthermore, the width of the optical feedback region 102 (core 115) on a closer side to the laser active region 101 (the width of the core 115 at a connection portion thereof with the active layer 113) and the width of the optical feedback region 102 (core 115) at the reflection point 104 on an opposite side to the laser active region 101 are set to be different from each other, and thus it is possible to further increase the bandwidth by using the effect of PPR. The following describes this point in more detail.

For example, an InP-based vertical injection type laser using PPR can provide a band of 55 GHz, and a lateral current injection type laser formed on SiC can provide a band of 108 GHz. Photon-photon resonance occurs basically by an interaction between a laser oscillation mode and a side mode formed by optical feedback, and the bandwidth is increased at a frequency corresponding to a frequency interval between these modes. This is a resonance phenomenon between the two modes, and the number of PPR peaks is restricted to one.

Here, conceivably, when a high-order side mode is made to arise using four-wave mixing (FWM), which is a non-linear phenomenon (effect), it is possible to increase a PPR bandwidth by using resonance between the high-order mode (+1st order) and a 0th order. In the direct modulation laser according to the embodiment of the present invention, a high degree of light confinement in the active layer is achieved, which is advantageous in exerting a non-linear effect in the active layer. As described earlier, the width of the core 115 at the reflection point 104 is set to be different from the width of the core 115 at the connection portion thereof with the active layer 113, and thus a high-order side mode (+1st order) can be made to arise using FWM. This can be formed in a Fabry-Perot mode using reflection at the reflection point 103 and reflection at the reflection point 104.

For example, the foregoing can be achieved when the width of the core 115 at the reflection point 104 is set to be larger than the width of the core 115 at the connection portion thereof with the active layer 113 so that the core 115 has a trapezoidal plan-view shape whose width gradually increases toward the reflection point 104. With such a shape, a reflectance at the reflection point 104 can be increased, which is advantageous in making a +1st order arise using FWM. Here, reflection at each of an interface between the DBR region 121 and the laser active region 101, the reflection point 103 (an interface between the laser active region 101 and the optical feedback region 102), and the reflection point 104 contributes to making the +1st order arise using FWM.

By the above-described resonance between the high-order side mode (+1st order) that has arisen using FWM and the 0th order, as shown in FIG. 9C, −1st order and ±2nd order modes are generated. An FSR interval can be adjusted using a waveguide length of the optical feedback region 102. Furthermore, a reflectance at the reflection point 104 can be further increased by increasing a width W of the core 115 at the reflection point 104 (FIG. 9D). In FIG. 9D, W=600 nm indicates a state where the width W of the core 115 at the reflection point 104 is equal to the width of the core 115 at the connection portion thereof with the active layer 113, which is a state where the core 115 has a rectangular parallelepiped plan-view shape.

Furthermore, when the 0th order mode and the 1st order mode overlap each other, PPR occurs by an interaction therebetween. In this case, however, the higher the above-described reflectance is, the larger the 1st order mode is, and thus there is a possibility that PPR can occur even at a more distant frequency.

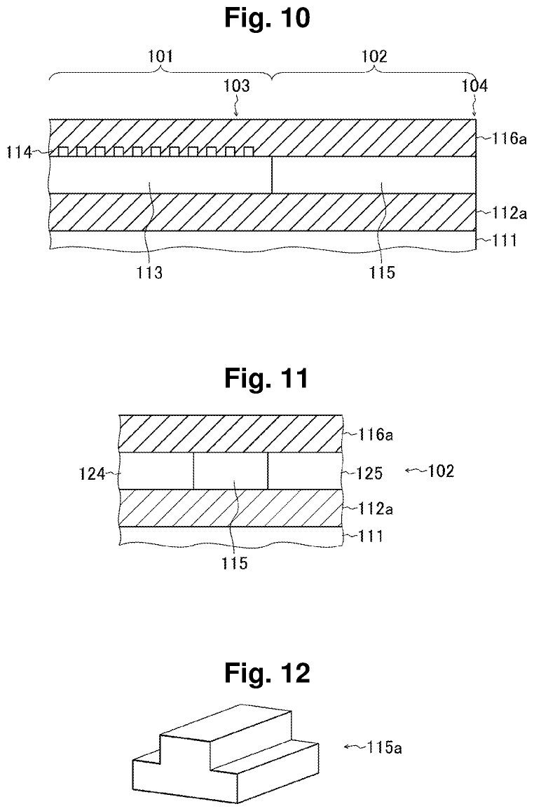

Next, with reference to FIGS. 10 and 11, a description is given of another direct modulation laser according to the embodiment of the present invention. FIG. 10 shows a section along a plane parallel to the waveguide direction, and FIG. 11 shows a section along a plane perpendicular to the waveguide direction. The direct modulation laser includes, in the direct modulation laser described with reference to FIGS. 6A and 6B, as a frequency adjustment mechanism, an n-type layer 124 and a p-type layer 125 arranged with the core 115 interposed therebetween in the optical feedback region 102. In this example, the substrate 111 is made of Si and a lower clad layer 112a is made of silicon oxide.

For example, a so-called forward voltage is applied to an n-i-p structure between the n-type layer 124 and the p-type layer 125, and thus a current injection mechanism for injecting a current into the core 115 can be obtained. Furthermore, a so-called reverse voltage is applied to the n-i-p structure between the n-type layer 124 and the p-type layer 125, and thus an electric field application mechanism for applying an electric field to the core 115 can be obtained.

Furthermore, in a configuration including the n-type layer 124 and the p-type layer 125, the core 115 can be made of a gain medium. In this configuration, a so-called forward voltage is applied to the n-i-p structure between the n-type layer 124 and the p-type layer 125, and thus the intensity of reflection light in the optical feedback region 102 can be amplified or attenuated.

By the way, in controlling coupling between laser light oscillated in the laser active region 101 and returned light from the optical feedback region 102, there are a configuration in which the intensity of the returned light from the optical feedback region 102 (an end face reflectance) is defined by a structure and a configuration in which the intensity of the returned light is defined by amplifying or attenuating the returned light as required during an operation. The configuration in which the end face reflectance is defined by a structure is exemplified by a configuration in which, as described earlier, the shape (sectional shape) of the core 115 of the optical feedback region 102 is changed. For example, with respect to a sectional-view shape of the active layer 113, the core 115 has a sectional-view shape having a decreased or increased width or an increased or decreased thickness. Furthermore, it is also possible to adopt a configuration in which the core 115 has a diameter decreasing or increasing with increasing distance from the active layer 113.

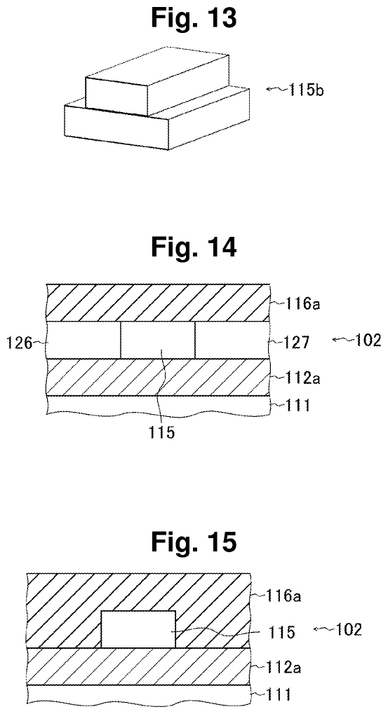

Furthermore, as shown in FIG. 12, there can be used a core 115a whose sectional shape perpendicular to the waveguide direction has multiple stages in a thickness direction thereof. Furthermore, as shown in FIG. 13, there can be used a core 115b whose sectional shape perpendicular to the waveguide direction has multiple stages in a thickness direction thereof, the multiple stages including an upper stage and a lower stage made of different materials from each other.

Furthermore, it is also possible to adopt a configuration in which, as shown in FIG. 14, in the optical feedback region 102, a layer 126 and a layer 127 made of a different material from that of the core 115 are provided with the core 115 interposed therebetween. The layers 126 and 127 can be made of, for example, InP. Furthermore, as shown in FIG. 15, it is also possible to form, in the optical feedback region 102, the upper clad layer 116a made of silicon oxide on the lower clad layer 112a made of silicon oxide so that the core 115 is buried in the upper clad layer 116a. FIGS. 14 and 15 show sections along a plane perpendicular to the waveguide direction.

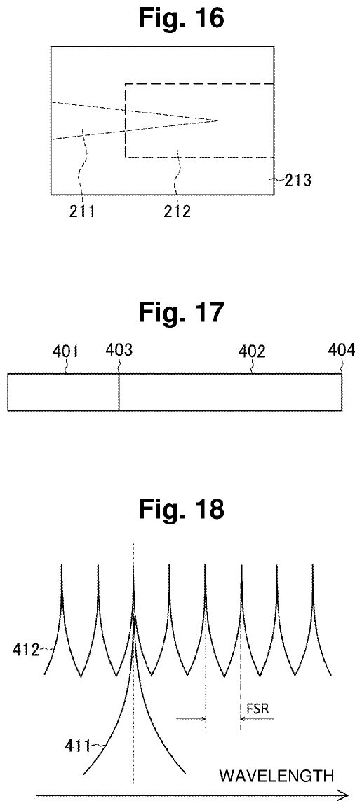

It is also possible to provide, at a light emitting portion of the direct modulation laser, a spot size conversion structure for reducing a loss of optical coupling with an optical fiber or an external optical waveguide. As shown in FIG. 16, the spot size conversion structure includes a conversion core 211 tapered with increasing distance from a point of connection, a first clad 212 formed to cover a tapered tip area of the conversion core 211, and a second clad 213 formed to cover the conversion core 211 and the first clad 212. The magnitude of their respective refractive indices increases in an order expressed by the conversion core 211<the first clad 212<the second clad 213.

Furthermore, it is also possible to adopt a configuration in which an optically connected DBR region is provided on an opposite side of the optical feedback region 102 to a connection end thereof with the laser active region 101. With the DBR region provided in this manner, in the optical feedback region 102, a reflectance at a DBR wavelength can be selectively increased. Furthermore, with the DBR region provided in this manner, a reflection point can be formed. These factors enable PPR to occur even in a case where the frequency difference ΔF is large(=the bandwidth is increasable at a high frequency).

Furthermore, it is also possible to adopt a configuration in which an optically connected DBR region is provided at each of both ends of the optical feedback region 102. In this case, the optical feedback region 102 and the laser active region 101 are connected to each other with the DBR region interposed therebetween. With this configuration, selectivity of a reflection wavelength in the optical feedback region 102 can be further enhanced. As a result, an interaction between laser light generated in the laser active region 101 and a Fabry-Perot type resonance mode formed in the optical feedback region 102 can be more strongly generated than in the above-described configuration.

As discussed above, according to embodiments of the present invention, laser oscillation is performed using photon-photon resonance that occurs depending on a frequency difference between a frequency of light generated in the laser active region and a frequency of the Fabry-Perot mode in the optical feedback region, and thus it is possible to change a frequency at which responsiveness is enhanced by PPR without the need to increase the length of the optical feedback region.

The present invention is not limited to the foregoing embodiments, and it is evident that many modifications and combinations can be made by those skilled in the art within the technical idea of the present invention.

### Reference Signs List

101 laser active region
102 optical feedback region
103 reflection point
104 reflection point

1-9. (canceled)

10. A direct modulation laser, comprising:
a distributed feedback type laser active region on a substrate; and
a Fabry-Perot type optical feedback region having an optical waveguide structure, the optical feedback region being on the substrate, being optically connected to one end of the laser active region in a waveguide direction, and having reflection points at both ends thereof in the waveguide direction,
wherein the direct modulation laser is configured to perform laser oscillation by using photon-photon resonance configured to occur depending on a frequency difference between a frequency of light generated in the laser active region and a frequency of a Fabry-Perot mode in the optical feedback region.

11. The direct modulation laser according to claim 10, further comprising:
a frequency adjuster configured to adjust a frequency of the Fabry-Perot mode in the optical feedback region by injecting a current into the optical feedback region, by controlling a temperature in the optical feedback region, or by applying an electric field to the optical feedback region.

12. The direct modulation laser according to claim 10, wherein
the laser active region includes a current injector configured to inject a current in a plane direction of the substrate.

13. The direct modulation laser according to claim 10, further comprising:
a distributed Bragg reflector (DBR) region on the substrate and optically connected to another end of the laser active region in the waveguide direction.

14. The direct modulation laser according to claim 13, wherein
a width of the optical feedback region on a closer side to the laser active region and a width of the optical feedback region at a reflection point on an opposite side to the laser active region are set to be different from each other.

15. The direct modulation laser according to claim 10, further comprising:
an optically connected distributed Bragg reflector (DBR) region on the substrate and provided on an opposite side of the optical feedback region to the laser active region in the waveguide direction.

16. The direct modulation laser according to claim 10, wherein
a core of the optical feedback region is different in at least one of thickness and width from a core of the laser active region.

17. The direct modulation laser according to claim 10, wherein the optical feedback region includes:
a core made of a gain medium; and
a current injector configured to inject a current into the core.

18. The direct modulation laser according to claim 10, wherein
a core of the optical feedback region has a sectional shape perpendicular to the waveguide direction, the sectional shape having multiple stages in a thickness direction of the core.

19. A direct modulation laser, comprising:
a laser active region on a substrate;
an optical feedback region on the substrate and having an optical waveguide structure, the optical feedback region being optically connected to one end of the laser active region in a waveguide direction, and having reflection points at both ends thereof in the waveguide direction; and
a frequency adjuster configured to adjust a frequency of a Fabry-Perot mode in the optical feedback region by injecting a current into the optical feedback region, by controlling a temperature in the optical feedback region, or by applying an electric field to the optical feedback region,
wherein the direct modulation laser is configured to perform laser oscillation by using photon-photon resonance, the photon-photon resonance being configured to be independent of a length of the optical feedback region in the waveguide direction.

20. The direct modulation laser according to claim 19, wherein
the laser active region includes a current injector configured to inject a current in a plane direction of the substrate.

21. The direct modulation laser according to claim 19, further comprising:
a distributed Bragg reflector (DBR) region on the substrate and optically connected to another end of the laser active region in the waveguide direction.

22. The direction modulation laser according to claim 19, wherein
the photon-photon resonance being configured to occur depending on a frequency difference between a frequency of light generated in the laser active region and a frequency of the Fabry-Perot mode in the optical feedback region.
